(19) United States
(12) Patent Application Publication
(10) Pub. No.: US 2009/0096076 A1
(43) Pub. Date: Apr. 16, 2009

(54) STACKED SEMICONDUCTOR PACKAGE WITHOUT REDUCTION IN STATA STORAGE CAPACITY AND METHOD FOR MANUFACTURING THE SAME

(76) Inventor: Young Hy JUNG, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 11/940,812

(22) Filed: Nov. 15, 2007

(30) Foreign Application Priority Data
Oct. 16, 2007 (KR) 10-2007-0103881
Oct. 23, 2007 (KR) 10-2007-0106480

(51) Int. Cl. H01L 21/50; H01L 23/02

(52) U.S. Cl. 257/686; 438/109; 257/E23.18

(57) ABSTRACT

A stacked semiconductor package includes a semiconductor chip module including at least two semiconductor chips with a semiconductor chip body having an upper surface, a lower surface, side surfaces coupling the upper surface and the lower surface, and a circuit part. The semiconductor chips include pads coupled to the circuit part and disposed at an edge of the upper surface. A recess parts are concavely formed in the side surfaces corresponding to each pad. Conductive connection patterns cover the recess parts, and each conductive connection pattern is electrically connected to a corresponding bonding pad. The semiconductor chip module is disposed on a substrate, and the contact pads of the semiconductor substrate are electrically connected to the conductive connection patterns. The stacked semiconductor package provides an improved structure that can contain a plurality of stacked semiconductor chips with no reduction in data storage capacity.

### CROSS-REFERENCE TO RELATED APPLICATIONS

The present application claims priority to Korean patent application number 10-2007-0103881 filed on Oct. 16, 2007 and 10-2007-0106480 filed on Oct. 23, 2007, which are incorporated herein by reference in its entirety.

### BACKGROUND OF THE INVENTION

The present invention relates to a stacked semiconductor package and a method for manufacturing the same, and more particularly to a stacked semiconductor package having an improved structure which prevents a reduction in data storage capacity.

Recent developments in semiconductor manufacturing technology have lead to the development of various types of semiconductor packages with semiconductor devices suitable for processing more data within a short time.

A semiconductor package is typically manufactured through a semiconductor chip manufacturing process that manufactures semiconductor chips including semiconductor devices on a wafer made of high purity silicon, a die sorting process that electrically tests semiconductor chips, and a packaging process that packages good semiconductor chips.

Examples of recent developments include, a chip scale package where the size of the semiconductor package is only 100% to 105% of the size of a semiconductor chip and a stacked semiconductor package where a plurality of semiconductor chips are stacked on each other in order to improve the data capacity and processing speed of a semiconductor device.

In the stacked semiconductor package where the plurality of semiconductor chips are stacked on each other, holes are formed in order to electrically connect the stacked semiconductor chips. The semiconductor chips are formed with through holes and the through holes are formed with through electrodes.

During the manufacturing process of the stacked semiconductor package, when the through electrodes (which penetrating through each semiconductor chip) are formed they occupy space, which causes a reduction in the data capacity of each semiconductor chip.

Further, when the semiconductor chips are formed with the through electrodes, damage can occur to the semiconductor chips. Therefore, a need exists for a semiconductor chip that can be applied to a stacked semiconductor package using only the through hole.

### BRIEF SUMMARY OF THE INVENTION

It is an object of the present invention to provide an improved structure for a stacked semiconductor package having a plurality of stacked semiconductor chips so that there is no reduction in data storage capacity.

It is another object of the present invention to provide a method for manufacturing the stacked semiconductor package.

There is provided a stacked semiconductor package according to the present invention comprising: a semiconductor chip module including at least two semiconductor chips that are stacked, with a semiconductor chip body having an upper surface, a lower surface, side surfaces coupling the upper surface and the lower surface, and a circuit part. Pads are disposed at an edge of the upper surface and coupled to the circuit part. Recess parts are concavely formed in the side surfaces of the semiconductor chip corresponding to each pad. Conductive connection patterns cover the recess parts and are also electrically connected to the corresponding pads. The conductive connection patterns of the stacked semiconductor chips are electrically interconnected. The semiconductor chip module is then disposed on a substrate having and contact pads of the substrate are electrically connected to the conductive connection patterns of the semiconductor chips.

The conductive connection pattern of the stacked semiconductor package covers the surface of the recess part and comprises a metal seed pattern electrically connected to the pad.

The recess part and the pad of the stacked semiconductor package may be adjacent to each other such that the recess part and the pad contact each other.

The recess part and the pad of the stacked semiconductor package may also be spaced from each other.

The conductive connection pattern of the stacked semiconductor package may comprise a solder.

Insulating adhesive members are interposed between the semiconductor chips of the stacked semiconductor package.

The pads of the semiconductor chip body may alternatively be disposed at the central portion of the semiconductor chip body. The pads are then electrically connected to the conductive connection pattern by means of a redistribution

The conductive connection pattern of the stacked semiconductor package may have a semi-cylindrical shape.

The pair of neighboring semiconductor chips of the stacked semiconductor package are spaced from each other by the insulating adhesive member, and the corresponding conductive contact members of the neighboring semiconductor chips are physically connected.

There is a provided a method for manufacturing a stacked semiconductor package comprising the steps of: manufacturing a wafer with preliminary semiconductor chips coupled to each other by means of cutting parts. The preliminary semiconductor chips have pads coupled to the circuit part. Penetration parts are formed and the penetration parts penetrate through the cutting parts corresponding to each pad. Preliminary conductive connection patterns are formed on surfaces of the penetration part. The preliminary conductive connection patterns are electrically connecting to corresponding pads. The semiconductor chips on the wafer are separated by cutting the cutting parts. The conductive connection patterns are then electrically connected to contact pads of a substrate.

During the step of forming the penetration part, the penetration part is formed in a cylindrical shape.

The step of forming the preliminary conductive connection pattern comprises forming mask patterns having openings exposing the pads and the penetration parts. A metal seed pattern is then formed on surfaces of the penetration parts and the pads exposed by means of the openings. The preliminary conductive connection patterns are then formed on the metal seed patterns by using the metal seed patterns.

The metal seed pattern may be formed by means of an electroless plating method.

The conductive pattern may be formed by means of an electro plating method.

The conductive pattern may comprise a solder.

After the step of manufacturing the semiconductor chips, the method further comprises mutually stacking at least two semiconductor chips and electrically connecting the conductive connection patterns of each semiconductor chip.

The method for manufacturing the stacked semiconductor package further comprises forming adhesive members between the semiconductor chips.

The step of electrically connecting the neighboring conductive connection patterns further comprises melting the conductive connection patterns.

### BRIEF DESCRIPTION OF THE DRAWINGS

FIG. 1 is a partial cut perspective view showing a stacked semiconductor package according to an embodiment of the present invention.

FIG. 2 is a partial cut perspective view showing any one of the semiconductor chips among the semiconductor chip modules shown in FIG. 1.

FIG. 3 is a cross-sectional view taken along line I-I′ of FIG. 2.

FIG. 4 is a partial enlarged view of a portion ‘A’ of FIG. 3.

FIG. 5 is a cross-sectional view taken along line II-II′ of FIG. 1.

FIG. 6 is a plan view showing a semiconductor chip according to another embodiment of the present invention.

FIGS. 7 to 16 are plan views and cross-sectional views showing a method for manufacturing a stacked semiconductor package according to an embodiment of the present invention.

### DESCRIPTION OF SPECIFIC EMBODIMENTS

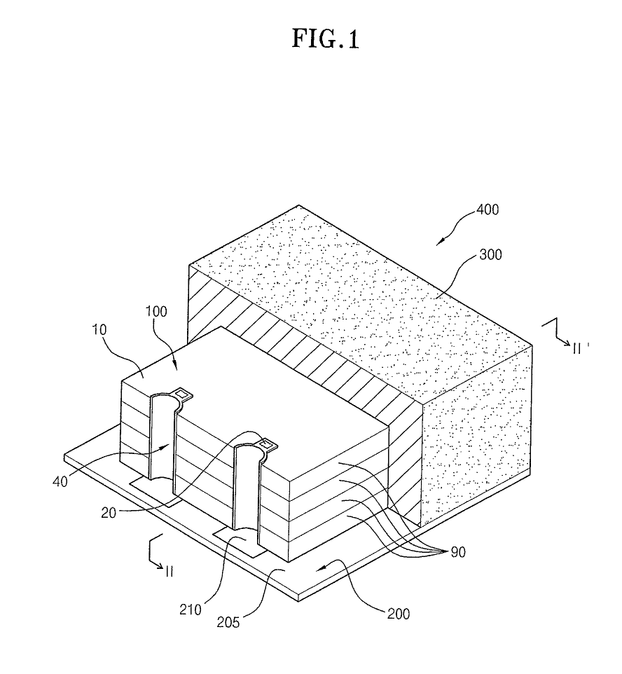

FIG. 1 is a partial cut perspective view showing a stacked semiconductor package according to an embodiment of the present invention.

Referring to FIG. 1, a stacked semiconductor package 400 comprises semiconductor chip module 100 and a substrate 200. The stacked semiconductor package 400 additionally comprises a molding member 300.

The semiconductor chip module 100 comprises at least two semiconductor chips 90 stacked on each other. As an example, in the embodiment shown in FIG. 1, the semiconductor chip module 100 comprises four semiconductor chips 90.

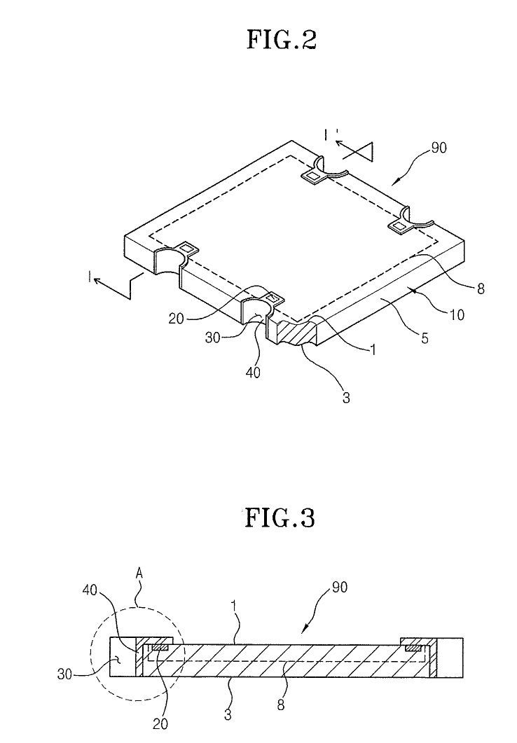

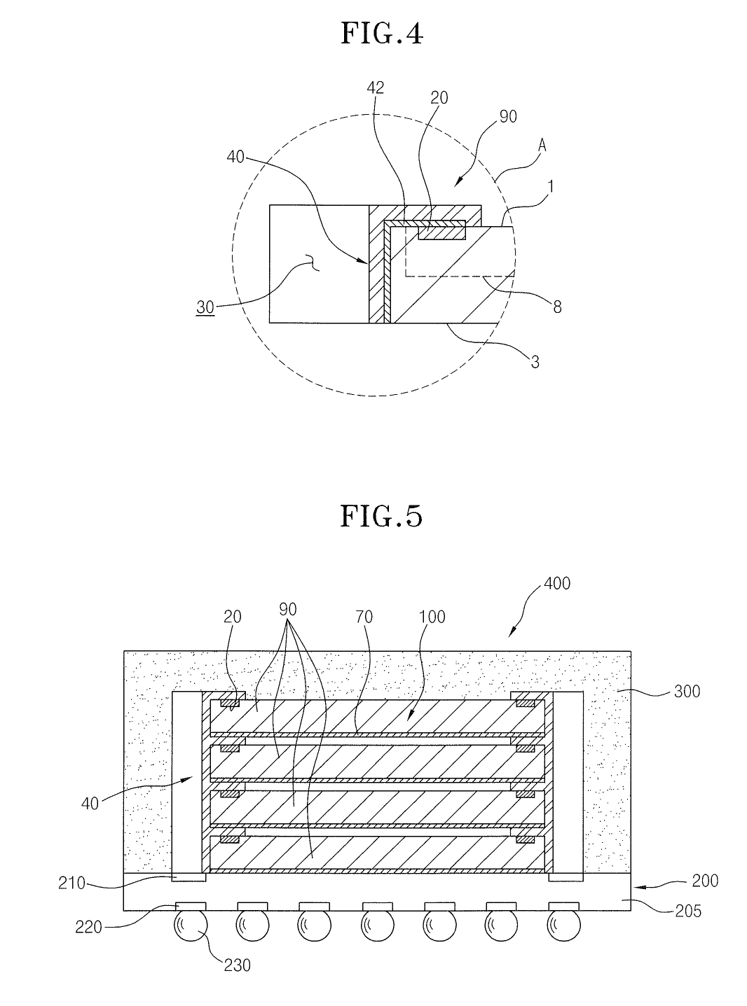

FIG. 2 is a partial cut perspective view showing any one of the semiconductor chips among the semiconductor chip modules shown in FIG. 1. FIG. 3 is a cross-sectional view taken along line I-I′ of FIG. 2. FIG. 4 is a partial enlarged view of a portion ‘A’ of FIG. 3.

Referring to FIGS. 2 and 3, each semiconductor chip 90 of the semiconductor chip module 100 comprises a semiconductor chip body 10, pads 20, recess parts 30, and conductive connection patterns 40.

The semiconductor chip body 10 has a rectangular parallelepiped shape. The semiconductor chip body 10 having the rectangular parallelepiped shape comprises an upper surface 1, a lower surface 3 facing the upper surface 1, side surfaces 5 coupling the upper surface 1 and the lower surface 3, and a circuit part 8. The semiconductor chip body 10 having the rectangular parallelepiped shape comprises four side surfaces 5. The circuit part 8 comprises devices such as transistors, capacitors, resistors, etc., in order to store and process data.

The pads 20 are disposed on the upper surface 1 of the semiconductor chip body 10. The pads 20 are electrically connected to the circuit part 8. The pads 20 electrically connected to the circuit part 8 may be disposed, for example, at an edge portion of the upper surface 1.

Recess parts 30 are disposed in the side surfaces 5 of the semiconductor chip body 10. For example, the recess parts 30 may be disposed in a pair of side surfaces 5 that faces each other. The recess part 30 has a concave recess shape formed in the side surface 5. In the to present embodiment, the recess parts 30 are disposed at positions corresponding to each pad 20.

In the present embodiment, the side surfaces 5 of the semiconductor chip body 10 may be formed, for example, with grooves in a semicircular shape by means of the recess part 30. The recess part 30 couples the upper surface 1 and the lower surface 3 of the semiconductor chip body 10.

In the present embodiment, when the grooves in the semicircular shape are formed in the side surfaces 5 of the semiconductor chip body 10 by means of the recess part 30, the area of the circuit 8 is increased making it possible to significantly improve the data storage capacity of the circuit part 8.

The pads 20 and the recess parts 30 corresponding to each pad 20 may be disposed adjacent to each other. Alternatively, the pads 20 and the recess parts 30 corresponding to each pad 20 may be spaced apart from each other. In embodiment shown in FIGS. 2 and 3, the pads 20 and the recess parts 30 corresponding to each pad 20 are disposed to be adjacent to each other.

The conductive connection patterns 40 cover the grooves formed in the side surfaces 5 of the semiconductor chip body 10. Portions of the conductive connection patterns 40 cover the corresponding pads 20 disposed on the upper surface 1 of the semiconductor chip body 10. The conductive connection pattern 40 has, for example, a semi-cylindrical shape.

Referring to FIG. 4, the conductive connection patterns 40 may comprise metal seed patterns 42. The metal seed pattern 42 covers the pad 20 and the groove formed in the side surface 5 of the semiconductor chip body 10. In the present embodiment, examples of materials usable for the metal seed pattern 42 include titanium, nickel, vanadium, etc.

The conductive connection pattern 40 may be a metal with a low melting point, such as a metal having a melting point similar to lead. In the present embodiment, the conductive connection pattern 40 disposed on the metal seed pattern 42 may comprise a solder. In the present embodiment, the metal seed pattern 42 and the conductive connection pattern 40 have substantially the same shape and size.

FIG. 5 is a cross-sectional view taken along line II-II′ of FIG. 1.

Referring to FIGS. 1 and 5, the semiconductor chip module 100 comprises at least two semiconductor chips 90 (shown in FIG. 2), wherein the semiconductor chips 90 are stacked on each other in a vertical direction.

In order to stack the semiconductor chips 90, on the upper surface 1 and the lower surface 3 of each other, the semiconductor chips 90 are disposed with insulating adhesive members 70. The insulating adhesive members 70 are used to attach the stacked semiconductor chips 90 to each other, and pairs of neighboring semiconductor chips 90 are spaced apart by means of the thickness of the insulating adhesive members 70.

As well as attaching the stacked semiconductor chips 90, the insulating adhesive member 70 additionally prevents an electrical short between the pad 40 of a lower semiconductor chip and an upper semiconductor chip disposed on the lower semiconductor chip.

Each conductive connection pattern 40 of the stacked semiconductor chips 90 is aligned in the same position so that the respective conductive connection patterns 40 of the stacked semiconductor chips 90 overlap each other. The aligned conductive connection patterns 40 are electrically interconnected by means such as a reflow method, etc. As a result, the conductive connection patterns 40 of the respective semiconductor chips 90 are integrally formed.

In the present embodiment, the semiconductor chip bodies 10 of each of the stacked semiconductor chips 90 are spaced from each other by means of the insulating adhesive member 70, but each of the conductive connection patterns 40 including the solder is electrically connected.

A substrate 200 has a substrate body 205, contact pads 210, and ball lands 220. A semiconductor chip module 100 is mounted to the upper surface of the substrate body 205 of the substrate 200.

The substrate body 205 may have, for example, a rectangular parallelepiped plate shape. The substrate body 205 may be, for example, a printed circuit board.

The contact pad 210 is disposed on the upper surface of the substrate body 205. Each contact pads 210 is disposed at a position corresponding to each conductive connection pattern 40 of the semiconductor chip module 100. In the present embodiment, the contact pad 210 may have a quadrangular shape when viewing from a plane.

The ball lands 220 are disposed on the upper surface of the substrate body 205 and a lower surface opposed thereto. Each ball land 220 is electrically connected to each contact pad 210 through the substrate body 205. A conductive member 230, such as a solder ball, is electrically connected to the ball land 220.

Referring to FIG. 5, the contact pad 210 of the substrate 200 is electrically connected to the conductive connection pattern 40 of the semiconductor chip module.

The molding member 300 covers the upper surface of the substrate 200 and the semiconductor chip module 100 to protect the semiconductor chip module 100 from impact and/or vibration applied from an external source.

In the present embodiment, Examples of materials that may be used for the molding member 300 in the present embodiment include epoxy resin, etc.

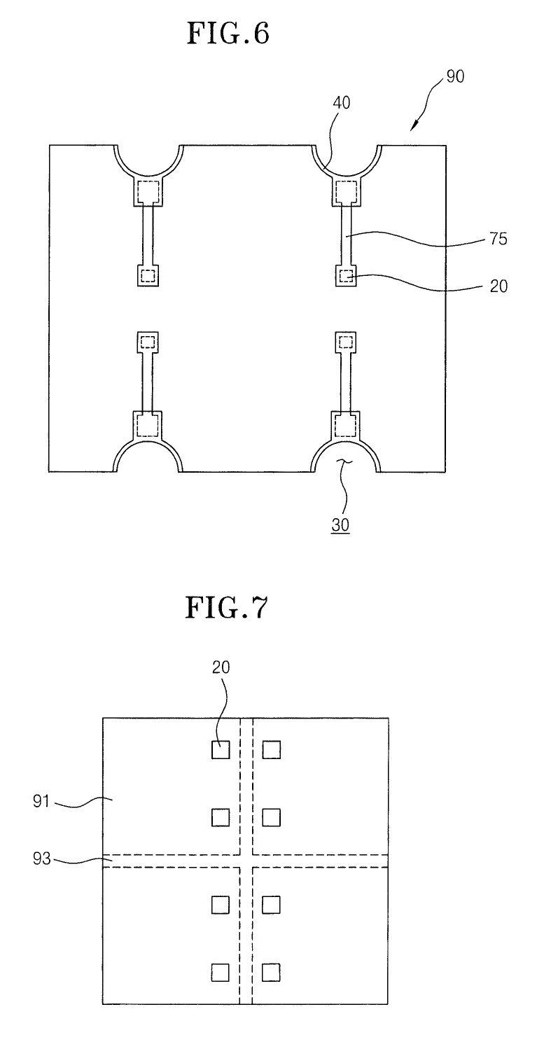

Although embodiment shows in FIGS. 1-5 and explains above that the pad 20 of the semiconductor 90 is disposed at the edge of the upper surface 1 of the semiconductor chip body 10. Alternatively, as shown in FIG. 6, the pad 20 may be disposed at the central portion of the upper surface of the semiconductor chip body 10, and electrically connected to the conductive connection pattern 40 using a redistribution 75.

FIGS. 7 to 16 are plan views and cross-sectional views showing a method for manufacturing a stacked semiconductor package according to an embodiment of the present invention.

FIG. 7 is a plan view showing preliminary semiconductor chips.

Referring to FIG. 7, at least two preliminary semiconductor chips 91 are manufactured on a wafer when manufacturing the stacked semiconductor package.

In the present embodiment, cutting parts 93 are formed between the neighboring preliminary semiconductor chips 91 disposed on the wafer. The preliminary semiconductor chips 91 are integrally formed.

Each preliminary semiconductor chip 91 has a circuit part (not shown) for storing and/or processing data and pads 20 that are electrically connected to the circuit part. The pads 20 are disposed along the edges adjacent to the cutting parts 93 in the respective preliminary semiconductor chips 91. As can be clearly seen in FIG. 7, the pads 20 of the neighboring preliminary semiconductor chips 91 are disposed adjacent to both sides of the cutting part 93.

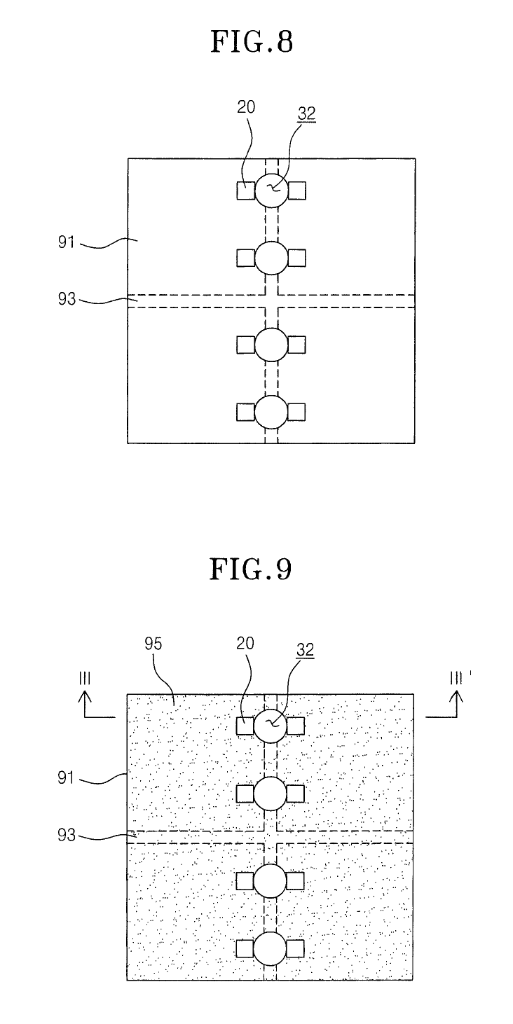

FIG. 8 is a plan view showing penetration parts formed at the cutting parts shown in FIG. 7.

Referring to FIG. 8, after the preliminary semiconductor chips 91 coupled to each other by means of the cutting parts 93 are manufactured, penetration parts 32 penetrating through the preliminary semiconductor chips 91 are formed at the cutting parts 93. The penetration part 32 may be formed, for example, by means of a laser drilling method, a drilling method, a photolithography process, etc.

A through hole in a cylindrical shape is formed on the cutting part 93 of the preliminary semiconductor chip 91 for the penetration part 32. Alternatively, there may be various types of hole shapes for the penetration part 32.

In the present embodiment, the penetration parts 32 are formed in positions corresponding to the pads 20 disposed in both sides of the cutting parts 93. The penetration parts 32 and each pad 20 disposed at both sides of the cutting parts 93 may be disposed adjacent to each other. Alternatively, the penetration parts 32 and each pad 20 disposed at both sides of the cutting parts 93 may be a predetermined distance from each other.

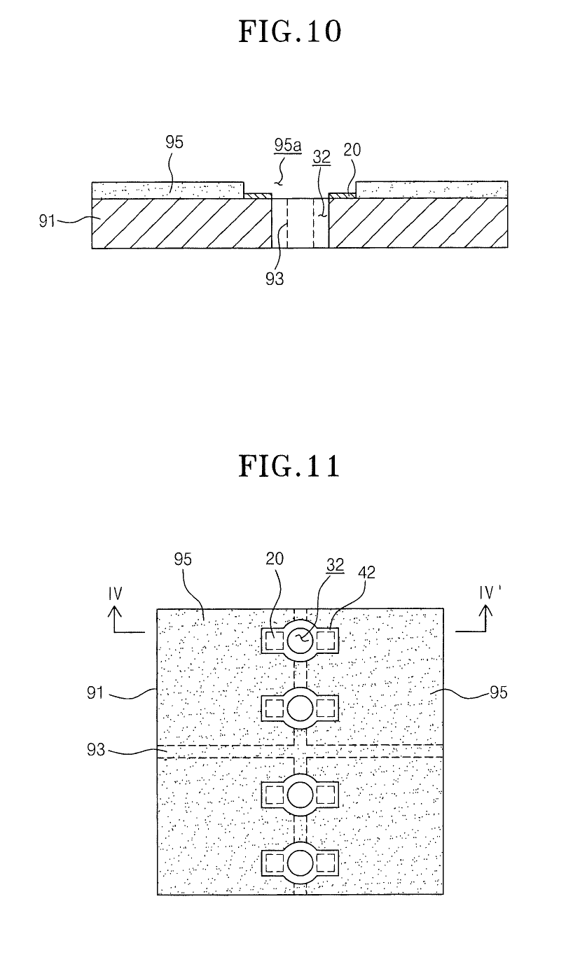

FIG. 9 is a plan view showing the preliminary semiconductor chips including mask patterns exposing the pads and the penetration parts shown in FIG. 8. FIG. 10 is a cross-sectional view taken along line III-III′ of FIG. 9.

Referring to FIGS. 9 and 10, the mask patterns 95 are formed on the preliminary semiconductor chips 93 coupled to each other by means of the cutting parts 93.

In order to form the mask patterns 95 on the preliminary semiconductor chips 93, photoresist films (not shown) are formed on the preliminary semiconductor chips 93. The photoresist film is patterned using a photo process that includes a photolithography process and a development process. The photoresist film is formed on the preliminary semiconductor chip 93 with an opening 95a that exposes the pad 20 and the penetration part 32.

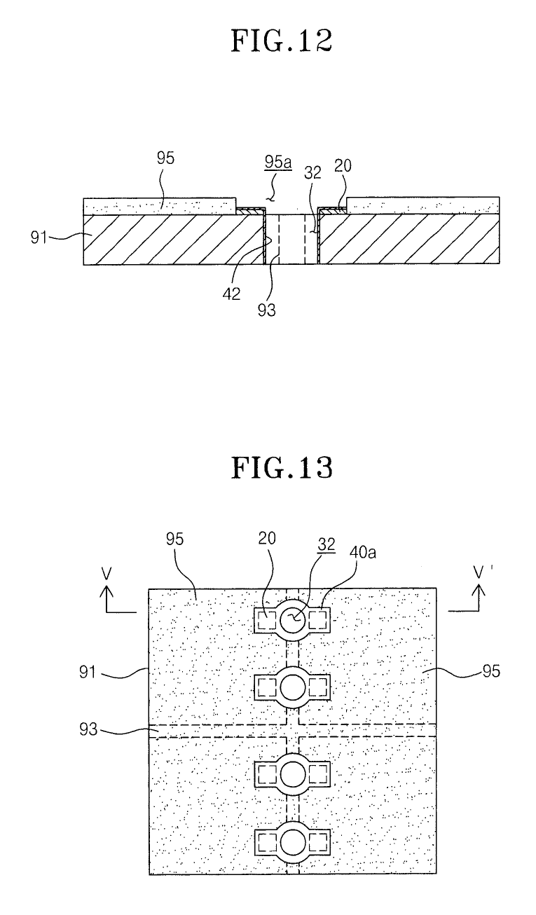

FIG. 11 is a plan view showing metal seed patterns that are formed on the pad and the penetration part, and that are exposed by means of the opening shown in FIG. 10. FIG. 12 is a cross-sectional view taken along line IV-IV′ of FIG. 11.

Referring to FIGS. 11 and 12, after the mask patterns 95 are formed on the preliminary semiconductor chips 93, the metal seed patterns 42 are formed on the surfaces of both the penetration parts 32 and the pads 20, which are exposed by means of the openings 95a in the mask pattern 95. The metal seed patterns 42 are formed using an electroless plating method. As a result, the surfaces of the pad 20 and the penetration part 32 are electrically connected. Examples of metal usable for the metal seed pattern 42 include titanium, nickel, vanadium, etc. Alternatively, the metal seed pattern 42 may be formed using a physical vapor deposition (PVD) process.

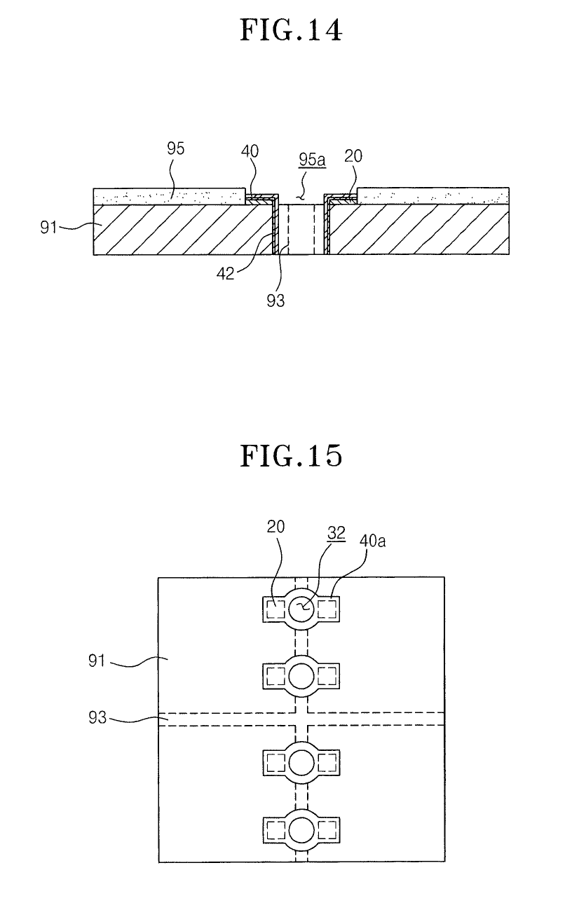

FIG. 13 is a plan view showing the formation of the conductive connection pattern on the metal seed pattern shown in FIG. 12. FIG. 14 is a cross-sectional view taken along line V-V′ of FIG. 13.

Referring to FIGS. 13 and 14, after the metal seed pattern 42 is formed on the surfaces of the pad 20 and the penetration part 32, the preliminary conductive connection pattern 40a is formed on the metal seed pattern 42. The preliminary conductive connection pattern 40a may be formed on the metal seed pattern 42 using, for example, an electro plating method. An example of a metal that may be used for the preliminary conductive connection pattern 40a includes a metal with a low melting point such as solder, etc. Alternatively, the preliminary conductive connection pattern 40a may be formed using a physical vapor deposition (PVD) process.

FIG. 15 is a plan view showing the removal of the mask pattern shown in FIG. 14 from the preliminary semiconductor chip.

Referring to FIG. 15, after forming the preliminary conductive connection pattern 40a on the metal seed pattern 42 of the preliminary semiconductor chip, the mask pattern 95 covering the upper surface of the preliminary semiconductor chip 91 is removed from the preliminary semiconductor chip 91. The mask pattern 95 is removed from the preliminary semiconductor chip 91 by means of a strip process or an ashing process.

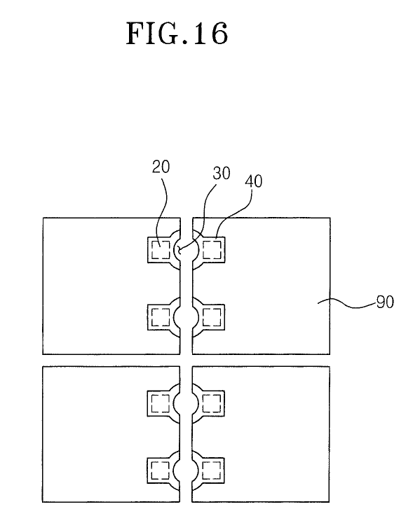

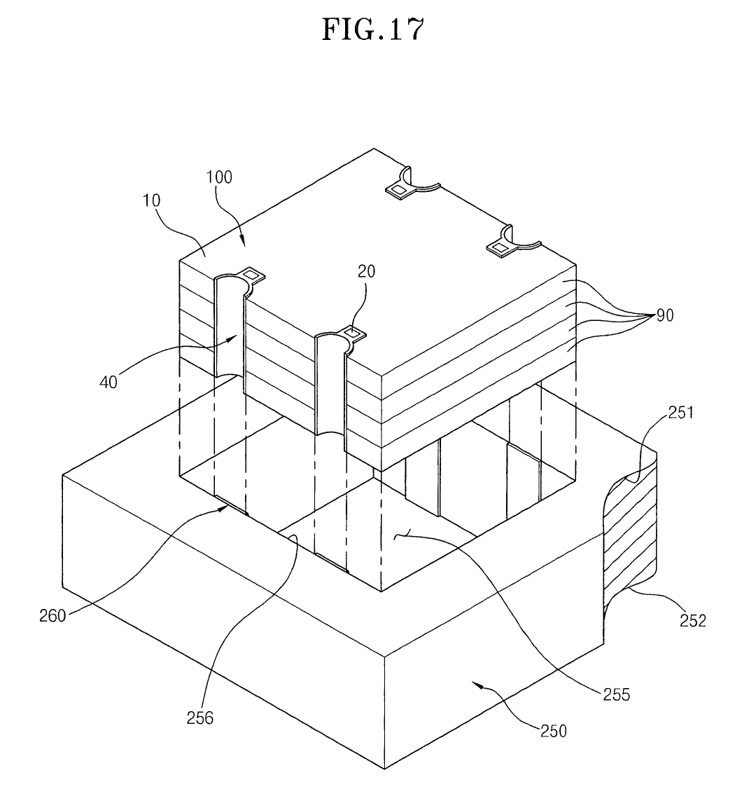

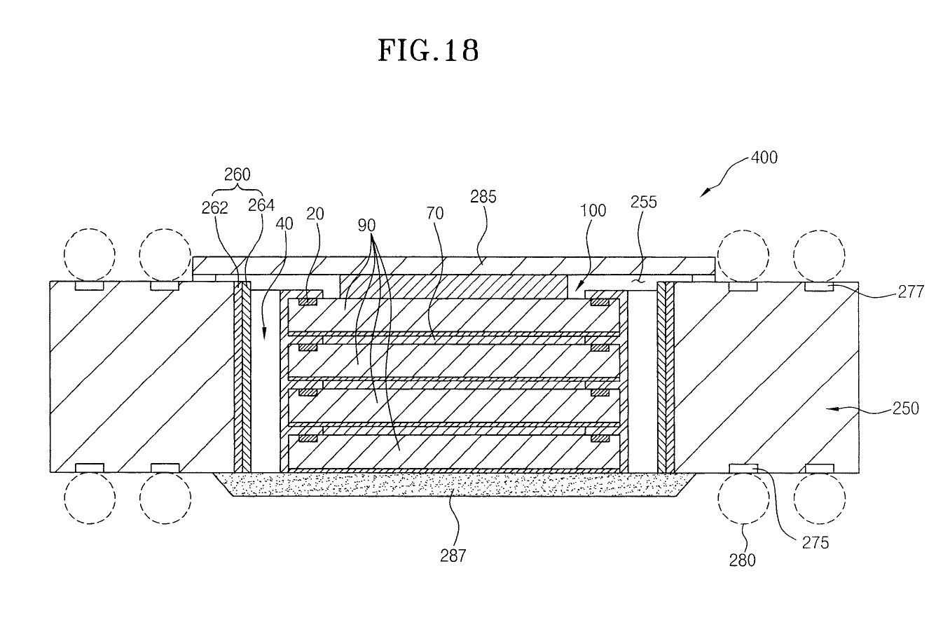

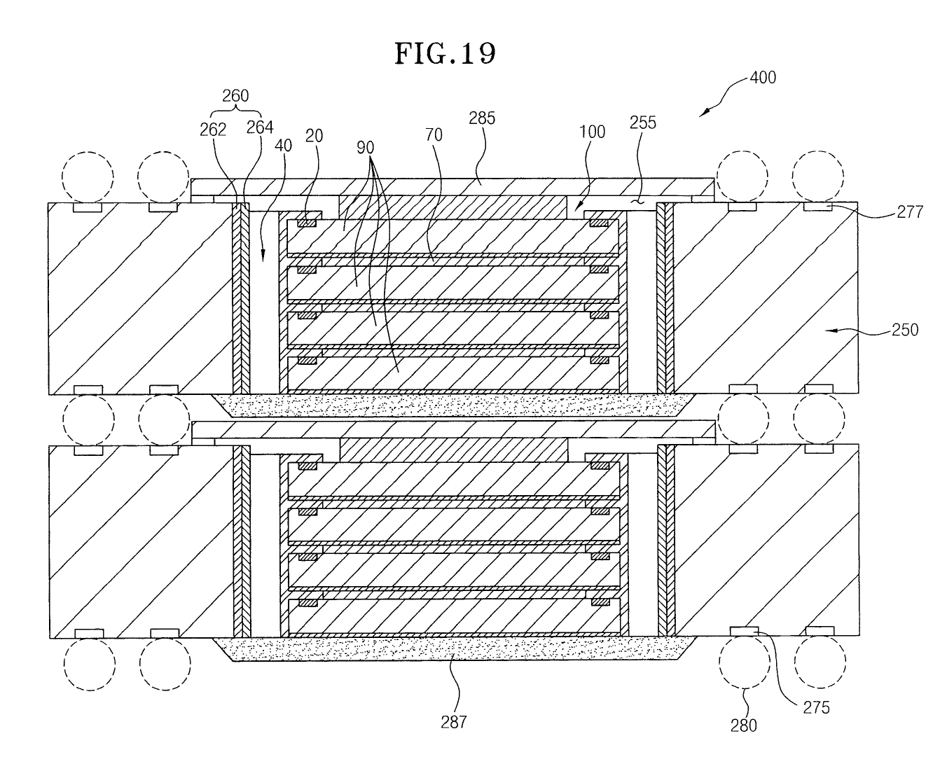

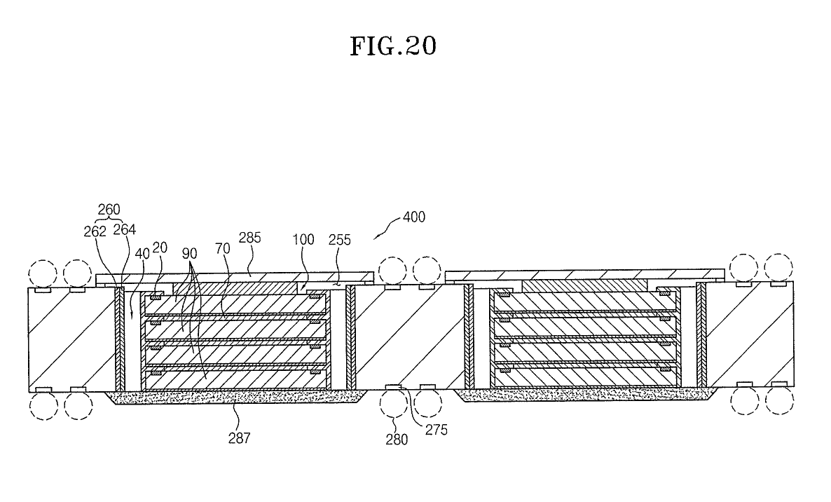

FIG. 16 is a plan view showing the formation of semiconductor chips for the stacked semiconductor package by cutting the preliminary semiconductor chips shown in FIG. 15.

Referring to FIGS. 1 to 16, after removing the mask patterns 95 from the preliminary semiconductor chips 91 the semiconductor chips 90 having the conductive connection patterns 40 are separated using the cutting parts 93 that had coupled the preliminary semiconductor chips 91.

Thereafter, the semiconductor chips 90 having the conductive connection patterns 40 are stacked on each other using the adhesive members. When stacking the semiconductor chips 90, the conductive connection patterns 40 of the stacked semiconductor chips 90 are aligned with each other. The conductive connection patterns 40 of the aligned semiconductor chips 90 are melted by the reflow process so that the respective conductive connection pattern 40 of the stacked semiconductor chips 90 are electrically interconnected, thereby manufacturing the semiconductor chip module 100.

After the semiconductor chip module 100 is manufactured, a semiconductor chip module 100 is disposed on the contact pads 210 on the substrate 200. The contact pad 210 of the semiconductor substrate and the conductive connection pattern 40 of the semiconductor chip module 100 are electrically interconnected.

After the semiconductor chip module 100 and the substrate 200 are coupled, the semiconductor chip module 100 is molded by means of the molding member 300 to manufacture the stacked semiconductor package 400 as seen in FIG. 1.

FIG. 17 is an exploded perspective view showing the stacked semiconductor package according to another embodiment of the present invention.

Referring to FIG. 17, the stacked semiconductor package 400 comprises the semiconductor chip module 100 and a receiving substrate 250.

The semiconductor chip module 100 comprises the stacked semiconductor chips 90. For example, in the embodiment shown in FIG. 17, the semiconductor chip module 100 comprises four semiconductor chips 90.

As shown in FIGS. 2 and 3 and as described above, the respective semiconductor chip 90 of the semiconductor chip module 100 comprises the semiconductor chip body 10, the pads 20, the recess parts 30, and the conductive connection patterns 40.

The semiconductor chip body 10 may have, for example, a rectangular parallelepiped shape. The semiconductor chip body 10 having the rectangular parallelepiped shape comprises an upper surface 1, a lower surface 3 facing the upper surface 1, side surfaces 5 that couple the upper surface 1 and the lower surface 3, and a circuit part 8. The semiconductor chip body 10 having the rectangular parallelepiped shape comprises the four side surfaces 5. The circuit part 8 comprises devices such as transistors, capacitors, and resistors for storing and processing data.

The pads 20 are disposed on the upper surface 1 of the semiconductor chip body 10. The pads 20 are electrically connected to the circuit part 8. The pads 20, which are electrically connected to the circuit part 8, may be disposed, for example, at the edge portions of the upper surface 1.

The recess parts 30 are disposed in the side surfaces 5 of the semiconductor chip body 10. For example, in FIG. 17, the recess parts 30 are disposed in a pair of side surfaces 5 that are facing each other. The recess part 30 has a concavely formed recess shape in the side surface 5. In the present embodiment, each recess part 30 is disposed at a position corresponding to each pad 20.

In the present embodiment, the side surfaces 5 of the semiconductor chip body 10 are formed, for example, with grooves in a semicircular shape by means of the recess part 30. The recess part 30 couples the upper surface 1 and the lower surface 3 of the semiconductor chip body 10.

In the present embodiment, when the grooves in the semicircular shape are formed in the side surfaces 5 of the semiconductor chip body 10 by means of the recess part 30, the area of the circuit 8 is increased, making it possible to significantly improve the data storage capacity of the circuit part 8.

The pads 20 and the recess parts 30 corresponding to each pad 20 may be disposed adjacent to each other. Alternatively, the pads 20 and the recess parts 30 corresponding to each pad 20 may be disposed may be spaced apart. In the present embodiment shown in FIG. 17, the pads 20 and the recess parts 30 corresponding to each pad 20 are disposed to be adjacent to each other.

The conductive connection patterns 40 cover the grooves formed in the side surfaces 5 of the semiconductor chip body 10. A portion of the conductive connection patterns 40 covers the pads 20 (which are disposed on the upper surface 1 of the semiconductor chip body 10). The conductive connection pattern 40 may have, for example, a semi-cylindrical shape.

Referring again to FIG. 4 as described above, the conductive connection patterns 40 may comprise metal seed patterns 42.

The metal seed pattern 42 covers the pad 20 and the groove formed at the side surface of the semiconductor chip body 10 by means of the recess part 30. In the present embodiment, examples of materials that may be used for the metal seed pattern 42 include: titanium, nickel, vanadium, etc.

The conductive connection pattern 40 may be a metal with a low melting point, such as a metal having a melting point similar to lead. In the present embodiment, the conductive connection pattern 40 disposed on the metal seed pattern 42 may comprise a solder. In the present embodiment, the metal seed pattern 42 and the conductive connection pattern 40 are substantially the same shape and size.

As described above, the semiconductor chips 90 shown in FIG. 2 are stacked as shown in FIG. 1 and as described above. For example, four semiconductor chips 90 are stacked.

In order to stack the plurality of semiconductor chips 90, insulating adhesive members 70 are disposed on the upper surface 1 and the lower surface 3 of the stacked semiconductor chip 90. The stacked semiconductor chips 90 are attached to each other by means of the insulating adhesive members 70. A pair of neighboring semiconductor chips 90 are spaced from each other by the thickness of the insulating adhesive member 70.

In addition to attaching the semiconductor chips 90, the insulating adhesive member 70 prevents electrical shorts between the pad 40 of the lower semiconductor chip and the upper semiconductor chip disposed on the lower semiconductor chip.

Each conductive connection pattern 40 of the stacked semiconductor chips 90 is aligned at the same position so that the conductive connection patterns 40 of the stacked semiconductor chips 90 overlap each other. The aligned conductive connection patterns 40 are electrically interconnected by means of a reflow method, etc. As a result, the conductive connection patterns 40 of the respective semiconductor chips 90 are electrically connected.

In the present embodiment, although the semiconductor chip bodies 10 of the stacked semiconductor chips 90 are spaced from each other by the insulating adhesive member 70, each of the conductive connection patterns 40 is electrically connected.

FIG. 18 is a cross-sectional view cutting the stacked semiconductor package shown in FIG. 17.

Referring to FIGS. 17 and 18, the receiving substrate 250 comprises a receiving part 255 and connection patterns 260.

The receiving substrate 250 comprising the receiving part 255 and the connection patterns 260 may have, for example, a plate shape. The receiving substrate 250 having the plate shape may be, for example, a printed circuit board (PCB).

The receiving part 255 may be, for example, at the central portion of the receiving substrate 250 and the receiving part 255 may be a through hole penetrating the upper surface 251 and the lower surface 252 of the receiving substrate 250. Alternatively, the receiving part 255 may be a recess that is formed at a predetermined depth from the upper surface 251 of the receiving substrate 250. The depth of the recess has a depth suitable for receiving the semiconductor chip module 100. In the present embodiment shown in FIGS. 17-18, the receiving part 255 is a through hole penetrating the upper surface 251 and the lower surface 252 of the receiving substrate 250.

The receiving part 255 receives the semiconductor chip module 100. In order to receive the semiconductor chip module 100, the receiving part 255 is slightly larger than the semiconductor chip module 100.

The connection pattern 260 is formed on the inner side surface of the receiving substrate 250 having the receiving part 255. The connection pattern 260 is selectively formed on the inner side surface facing the conductive connection pattern 40 of the semiconductor chip module 100.

Referring specifically to FIG. 18, the connection pattern 260 comprises a plating pattern 262 and a solder pattern 264.

The plating pattern 262 is disposed, for example, on the inner side surface 255 facing the conductive connection pattern 40. The plating pattern 262 may be formed using various plating methods. Examples of materials that may be used for the plating pattern 262 include titanium, nickel, vanadium, copper, etc.

The solder pattern 264 is selectively formed on the plating pattern 262. The solder pattern 264 is formed on the plating pattern 262. The solder pattern 264 is electrically connected to the conductive connection pattern 40 of the semiconductor chip module 100.

Ball land patterns 275 and 277 and may be formed on the upper surface 251 and the lower surface 252 of the receiving substrate 250 (which comprises the receiving part 255 and the connection pattern 260). The ball land patterns 275 and 277 are electrically connected to the connection patterns 260 of the receiving substrate 250.

Solder balls 280 may be formed on the ball land patterns 255 and 257.

The receiving substrate 250 may further comprise a cover 285 and a molding member 287. The cover 285 and the molding member 287 performs the following functions: protects the semiconductor chip module 100 in the receiving part 255 of the receiving substrate 250 from external impact and/or vibration, isolates the semiconductor chip module 100 from the external conductor, and rapidly discharges heat generated by the semiconductor chip module 100.

The cover 285 covers the upper portion of the semiconductor chip module 100 that is left exposed by the upper surface 251 of the receiving substrate 250. The cover 285 may include a metal. The molding member 287 covers the lower portion of the semiconductor chip module 100 that remains exposed by the lower surface 252 of the receiving substrate 250. The molding member 287 may include epoxy resin, etc.

As shown in FIG. 19, in the present embodiment, the stacked semiconductor packages 400 shown in FIGS. 17 and 18 may also be stacked. Alternatively, two or more receiving parts 255 may be formed in a receiving substrate 250 as shown in FIG. 20. In FIG. 20 each receiving part 255 receives the semiconductor chip module 100.

As explained in the aforementioned description, conductive connection members are provided to electrically interconnect the semiconductor chips that form a stacked semiconductor package. Utilizing the conductive connection members prevents both the reduction of data storage capacity in each semiconductor chip and damage to the semiconductor chips during the manufacturing of the stacked semiconductor package.

Although specific embodiments of the present invention have been described for illustrative purposes, those skilled in the art will appreciate that various modifications, additions, and substitutions are possible without departing from the scope and the spirit of the invention as disclosed in the accompanying claims.

What is claimed is:

1. A stacked semiconductor package comprising:
a semiconductor chip module including at least two semiconductor chips that are stacked upon each other, the semiconductor chips including a semiconductor chip body having an upper surface, a lower surface, side surfaces coupling the upper surface and the lower surface, and a circuit part, wherein each semiconductor chip comprises:
pads disposed on the upper surface of the semiconductor chips, wherein the pads are coupled to the circuit part
recess parts concavely formed in the side surfaces, wherein each recess part corresponds to a pad;
conductive connection patterns covering the recess parts, wherein the conductive connection patterns are electrically connected to the corresponding pads; and
wherein the conductive connection patterns of the semiconductor chips are electrically interconnected;
a substrate having the semiconductor chip module disposed thereon, wherein the substrate includes contact pads electrically connected to the conductive connection patterns.

2. The stacked semiconductor package according to claim 1, wherein the conductive connection pattern comprises a metal seed pattern electrically connected to the pad.

3. The stacked semiconductor package according to claim 1, wherein the recess part and the pad are adjacent to each other such that the recess part and the pad contact each other.

4. The stacked semiconductor package according to claim 1, wherein the recess part and the pad are spaced from each other.

5. The stacked semiconductor package according to claim 1, wherein the conductive connection pattern comprises a solder.

6. The stacked semiconductor package according to claim 1, wherein insulating adhesive members are interposed between the stacked semiconductor chips.

7. The stacked semiconductor package according to claim 1, wherein the pads are disposed at a central portion of the upper surface of the semiconductor chip body and are electrically connected to the conductive connection pattern by means of a redistribution

8. The stacked semiconductor package according to claim 1, wherein the conductive connection pattern has a semi-cylindrical shape.

9. The stacked semiconductor package according to claim 6, wherein a pair of neighboring semiconductor chips is spaced from each other by the insulating adhesive member, and the corresponding conductive contact members of the neighboring semiconductor chips are physically connected.

10. A method for manufacturing a stacked semiconductor package comprising the steps of:
manufacturing a wafer having preliminary semiconductor chips coupled to each other by means of cutting parts, wherein each preliminary semiconductor chip has pads coupled to a circuit part;
forming penetration parts penetrating through the cutting parts, wherein each penetration part corresponds to a pad;
forming preliminary conductive connection patterns on surfaces of the penetration part, wherein each preliminary conductive connection pattern is electrically connected to the corresponding pad;
separating the semiconductor chips on the wafer by cutting the cutting parts; electrically connecting the conductive connection patterns of the semiconductor chips to contact pads of a substrate.

11. The method according to claim 10, wherein during the step of forming the penetration part, the penetration part is formed in a cylindrical shape.

12. The method according to claim 10, wherein the step of forming the preliminary conductive connection pattern comprises:
forming mask patterns having openings exposing the pads and the penetration parts;
forming metal seed patterns on surfaces of the penetration parts and the pads exposed by means of the openings; and
forming the preliminary conductive connection patterns on the metal seed patterns.

13. The method according to claim 12, wherein the metal seed pattern is formed by an electroless plating method.

14. The method according to claim 12, wherein the conductive pattern is formed by an electro plating method.

15. The method according to claim 12, wherein the conductive pattern comprises a solder

16. The method according to claim 10, further comprising:
after the step of manufacturing the semiconductor chips, stacking at least two of the separated semiconductor chips upon each other, and electrically connecting the conductive connection patterns of each semiconductor chip.

17. The method according to claim 16, further comprising forming adhesive members between the semiconductor chips to attach the semiconductor chips to each other.

18. The method according to claim 16, wherein the step of electrically connecting the conductive connection patterns further comprises melting the conductive connection patterns.

19. A stacked semiconductor package comprising:
a semiconductor chip module including at least two semiconductor chips that are stacked upon each other, wherein the semiconductor chips include a semiconductor chip body having an upper surface, a lower surface, side surfaces coupling the upper surface and the lower surface, and a circuit part, the semiconductor chip comprising:
pads disposed on the upper surface of the semiconductor chips, wherein the pads are coupled to the circuit part;
recess parts concavely formed in the side surfaces, wherein each recess part corresponds to a pad;
conductive connection patterns covering the recess parts, wherein the conductive connection patterns are electrically connected to the corresponding pads;
wherein the conductive connection patterns of the semiconductor chips are electrically interconnected;
a receiving substrate for receiving the semiconductor chip module, the receiving substrate comprising:
a receiving part formed in the receiving substrate for receiving the semiconductor chip module;
connection patterns formed on an inner side surface of the receiving part, wherein the connection patterns correspond to the conductive connection patterns of the semiconductor chip module.

20. The stacked semiconductor package according to claim 19, wherein the receiving part of the receiving substrate is a through hole that penetrates an upper surface of the receiving substrate and a lower surface facing the upper surface of the receiving substrate.

21. The stacked semiconductor package according to claim 20, further comprising:
a cover formed over the upper surface of the receiving substrate to cover the semiconductor chip module; and
a molding member formed over the lower surface of the receiving substrate to cover the semiconductor chip module.

22. The stacked semiconductor package according to claim 19, wherein the connection patterns comprise plating patterns disposed on the inner side surface of the receiving part and solder patterns formed on the plating patterns and electrically connected to the conductive connection members.

23. The stacked semiconductor package according to claim 19, further comprising, ball land patterns formed on at least one of an upper surface of the receiving substrate and a lower surface of the receiving substrate, wherein the ball land patterns are electrically connected to the connection patterns.

24. The stacked semiconductor package according to claim 23, wherein at least two receiving substrates are stacked upon each other and the ball land patterns of each receiving substrate is electrically connected to the ball lands of the corresponding stacked receiving substrate by means of solder balls.

25. The stacked semiconductor package according to claim 19, wherein the receiving substrate comprises at least two receiving parts.
